(19) United States
(12) Patent Application Publication
(10) Pub. No.: US 2026/0221177 A1
(43) Pub. Date: Jul. 30, 2026

(54) DYNAMIC VOLTAGE DETERMINATION METHOD, SYSTEM, DEVICE AND STORAGE MEDIUM FOR LPDDR CHIP

(71) Applicant: Shenzhen Rayson Technology Co., Ltd., Shenzhen (CN)

(72) Inventor: Zi Liu, Shenzhen (CN)

(21) Appl. No.: 19/403,892

(22) Filed: Nov. 30, 2025

(30) Foreign Application Priority Data
Jan. 20, 2025 (CN) 2025100822767

(51) Int. Cl. G11C 11/4074; G11C 11/4076

(52) U.S. Cl. CPC G11C 11/4074; G11C 11/4076

(57) ABSTRACT

The disclosure discloses a dynamic voltage determination method, a system, a device, and storage medium for an LPDDR chip. The method comprises: obtaining process parameters of the LPDDR chip; determining a parameter type based on the process parameters, wherein the parameter type represents the type of the process parameters; determining a DVFSC mode of the LPDDR chip based on the parameter type and a preset data table; and determining a dynamic voltage of the LPDDR chip based on the DVFSC mode, the preset data table, and the process parameters. This application effectively addresses the shortcomings of existing methods by determining the DVFSC mode of the LPDDR chip based on its process parameters and then calculating the dynamic voltage under the DVFSC mode. Therefore, when the DVFSC mode is a low-frequency mode, it can calculate the corresponding dynamic voltage, improving the operational stability of the LPDDR chip.

### TECHNICAL FIELD

The disclosure relates to the field of memory testing technology, particularly to a dynamic voltage determination method, a system, a device, and storage medium for an LPDDR chip.

### BACKGROUND

LPDDR (Low-Power Double Data Rate SDRAM, low-power double-data-rate synchronous dynamic random-access memory) is a type of memory used in electronic devices with stringent power consumption requirements, such as mobile devices and IoT devices. It not only meets the device's needs for memory capacity and performance but also significantly reduces power consumption, thereby extending the device's battery life.

Existing LPDDR chips (especially LPDDR5) are unable to accurately calculate dynamic voltage when operating in low-frequency modes, resulting in unstable operation of the LPDDR chips.

### SUMMARY

In view of this, the purpose of the embodiments of the present disclosure is to provide a dynamic voltage determination method, a system, a device, and storage medium for an LPDDR chip, which can accurately calculate the dynamic voltage when the LPDDR chip is in a low-frequency mode, thereby improving the operational stability of the LPDDR chip.

In a first aspect, an embodiment of the present disclosure provides a dynamic voltage determination method for an LPDDR chip, comprising: obtaining process parameters of the LPDDR chip;
determining a parameter type based on the process parameters, wherein the parameter type represents the category of the process parameters;
determining a DVFSC mode of the LPDDR chip based on the parameter type and a preset data table;
determining a dynamic voltage of the LPDDR chip based on the DVFSC mode, the preset data table, and the process parameters.

In some optional embodiments, determining the parameter type based on the process parameters comprises:
determining parameter performance based on the process parameters;
when the parameter performance indicates that the process parameters are electrical performance parameters, configuring the process parameters indicating transistor electrical performance as a first type, and/or configuring the process parameters indicating load element electrical performance as a second type;
when the parameter performance indicates that the process parameters are physical performance parameters, configuring the process parameters indicating transistor physical performance as a third type, and/or configuring the process parameters indicating load element physical performance as a fourth type.

In some optional embodiments, determining the DVFSC mode of the LPDDR chip based on the parameter type and the preset data table comprises:
when the parameter type is configured as the first type, searching for a first mode corresponding to the first type in the preset data table and configuring the DVFSC mode as the first mode;
when the parameter type is configured as the second type, searching for a second mode corresponding to the second type in the preset data table and configuring the DVFSC mode as the second mode;
when the parameter type is configured as the third type, searching for a third mode corresponding to the third type in the preset data table and configuring the DVFSC mode as the third mode;
when the parameter type is configured as the fourth type, searching for a fourth mode corresponding to the fourth type in the preset data table and configuring the DVFSC mode as the fourth mode, wherein the first mode indicates a high-frequency mode, and the second mode and the third mode indicate low-frequency modes.

In some optional embodiments, determining the dynamic voltage of the LPDDR chip based on the DVFSC mode, the preset data table, and the process parameters, comprises:
identifying a target entry in the preset data table based on the DVFSC mode;
determining the dynamic voltage based on the process parameters and the target entry, wherein the dynamic voltage represents a preset voltage according to different process parameters.

In some optional embodiments, after identifying the target entry in the preset data table based on the DVFSC mode, the method further comprises:
determining a voltage calculation formula based on the target entry;
substituting the process parameters into the voltage calculation formula to calculate the dynamic voltage.

In some optional embodiments, determining the dynamic voltage based on the process parameters and the target entry comprises:
obtaining a first voltage corresponding to the process parameters of the first type in the target entry;
obtaining a second voltage corresponding to the process parameters of the second type in the target entry;
obtaining a third voltage corresponding to the process parameters of the third type in the target entry;
obtaining a fourth voltage corresponding to the process parameters of the fourth type in the target entry;
determining the dynamic voltage based on the first voltage, the second voltage, the third voltage, and the fourth voltage.

In some optional embodiments, determining the dynamic voltage based on the first voltage, the second voltage, the third voltage, and the fourth voltage, comprises:
obtaining a first weight coefficient for the first voltage, a second weight coefficient for the second voltage, a third weight coefficient for the third voltage, and a fourth weight coefficient for the fourth voltage;
calculating the dynamic voltage based on the first voltage, the first weight coefficient, the second voltage, the second weight coefficient, the third voltage, the third weight coefficient, the fourth voltage, and the fourth weight coefficient.

In a second aspect, an embodiment of the present disclosure provides a dynamic voltage determination system for an LPDDR chip, comprising:
a first module configured to obtain process parameters of the LPDDR chip;
   a second module configured to determine a parameter type based on the process parameters, wherein the parameter type represents the type of the process parameters;
   a third module configured to determine a DVFSC mode of the LPDDR chip based on the parameter type and a preset data table;
   a fourth module configured to determine a dynamic voltage of the LPDDR chip based on the DVFSC mode, the preset data table, and the process parameters.

In a third aspect, an embodiment of the present disclosure provides a memory testing device applicable to smart cards, the device comprising:
at least one processor;
   at least one memory configured to store at least one program;
   when the at least one program is executed by the at least one processor, the at least one processor is caused to implement the method as described above.

In a fourth aspect, an embodiment of the present disclosure provides a computer-readable storage medium storing a processor-executable program, wherein the processor-executable program, when executed by a processor, is configured to perform the method as described above.

Implementing the embodiments of the present disclosure comprises the following beneficial effects: An embodiment of the present disclosure provides a dynamic voltage determination method for an LPDDR chip, comprising: obtaining process parameters of the LPDDR chip; determining a parameter type based on the process parameters, wherein the parameter type represents the type of the process parameters; determining a DVFSC mode of the LPDDR chip based on the parameter type and a preset data table; and determining a dynamic voltage of the LPDDR chip based on the DVFSC mode, the preset data table, and the process parameters. This application effectively addresses the shortcomings of existing methods by determining the DVFSC mode of the LPDDR chip based on its process parameters and then calculating the dynamic voltage under the DVFSC mode. Therefore, when the DVFSC mode is a low-frequency mode, it can calculate the corresponding dynamic voltage, thereby improving the operational stability of the LPDDR chip.

### BRIEF DESCRIPTION OF THE DRAWINGS

FIG. 1 is a schematic flowchart illustrating the steps of a dynamic voltage determination method for an LPDDR chip provided in an embodiment of the present disclosure;

FIG. 2 is a structural block diagram of a dynamic voltage determination system for an LPDDR chip provided in an embodiment of the present disclosure;

FIG. 3 is a structural block diagram of a memory testing device provided in an embodiment of the present disclosure.

### DETAILED DESCRIPTION

In order to make the objectives, technical solutions, and advantages of the present disclosure clearer and more comprehensible, the present disclosure is further elaborated in detail below in conjunction with the accompanying drawings and embodiments. It should be understood that the specific embodiments described herein are merely intended to explain the present disclosure and are not intended to limit the scope of the present disclosure.

It should be noted that although functional modules are divided in the device schematic diagrams and logical sequences are shown in the flowcharts, in certain cases, the steps shown or described may be executed in a sequence different from the module divisions in the device or the sequence in the flowcharts. The terms “first,” “second,” etc., in the specification, claims, or the aforementioned drawings are used to distinguish similar objects and are not necessarily used to describe a specific order or sequence.

An embodiment of the present disclosure provides a dynamic voltage determination method for an LPDDR chip, comprising: obtaining process parameters of the LPDDR chip; determining a parameter type based on the process parameters, wherein the parameter type represents the type of the process parameters; determining a DVFSC mode of the LPDDR chip based on the parameter type and a preset data table; and determining a dynamic voltage of the LPDDR chip based on the DVFSC mode, the preset data table, and the process parameters. This application effectively addresses the shortcomings of existing methods by determining the DVFSC mode of the LPDDR chip based on its process parameters and then calculating the dynamic voltage under the DVFSC mode. Therefore, when the DVFSC mode is a low-frequency mode, it can calculate the corresponding dynamic voltage, thereby improving the operational stability of the LPDDR chip.

The following provides a further elaboration on the embodiments of the present disclosure with reference to the accompanying drawings.

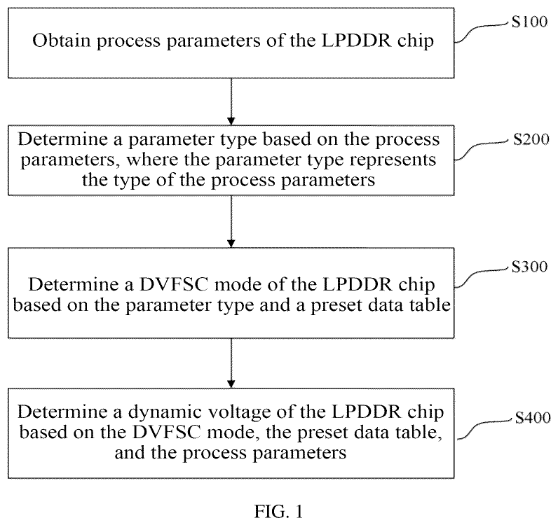

As shown in FIG. 1, an embodiment of the present disclosure provides a dynamic voltage determination method for an LPDDR chip, which comprises the following steps:
S100: obtaining process parameters of the LPDDR chip;
S200: determining a parameter type based on the process parameters, wherein the parameter type represents the type of the process parameters;
S300: determining a DVFSC mode of the LPDDR chip based on the parameter type and a preset data table;
S400: determining a dynamic voltage of the LPDDR chip based on the DVFSC mode, the preset data table, and the process parameters.

Specifically, the process parameters in this application can be obtained through design documents, measurements during the manufacturing process, and chip testing equipment, and the specific acquisition methods are not limited herein. The process parameters of an LPDDR chip play a decisive role in aspects such as the chip's performance, power consumption, and electromagnetic compatibility. Process parameters cover multiple aspects, for example, parameters at the transistor level, including channel length, channel width, threshold voltage, and doping concentration of transistors. The channel length and width affect the size of the transistor, which is in turn related to the integration density of the LPDDR chip and the electron migration speed; the threshold voltage determines the minimum voltage required for the transistor to turn on and conduct, having a significant impact on setting the operating voltage range of the entire LPDDR chip; the doping concentration is related to the carrier concentration, affecting the conductivity of the transistor. Additionally, parameters related to the physical structure of the LPDDR chip are also involved, such as the thickness of metal layers, the spacing between metal lines, and the thickness of insulating layers. Parameters related to metal layers affect the wiring resistance and capacitance inside the LPDDR chip, influencing signal transmission speed and power consumption; the thickness of the insulating layer is related to the voltage withstand capability and leakage current of the LPDDR chip. Besides, parameters related to passive components such as capacitors and resistors also jointly form the basis for the complex electrical characteristics of the LPDDR chip.

The type of process parameters is determined by analyzing the relationship between the process parameters and various performance indicators of the LPDDR chip and is identified with corresponding symbols.

The preset data table is compiled after extensive experimental testing, simulation analysis, and practical application feedback during the research and development process of the LPDDR chip. It records the optimal DVFSC (Dynamic Voltage and Frequency Scaling Control) modes of the LPDDR chip under various operating conditions for different combinations of parameter types. The table is arranged by different parameter type categories, with each row corresponding to a specific combination of parameter types and columns listing the corresponding DVFSC mode and relevant explanatory information. Once the parameter types corresponding to the chip's process parameters have been determined, the matching entry is looked up in the preset data table. By comparing the specific conditions of each parameter type, the row record that best matches the characteristics of the current LPDDR chip's process parameters is found, and the DVFSC mode specified in that row record is the suitable mode for the LPDDR chip. Different DVFSC modes specify the dynamic voltages of the LPDDR chip under different operating states.

In some embodiments, under a certain DVFSC mode, the dynamic voltage is associated with multiple factors of the LPDDR chip, such as its operating frequency, load conditions, and specific process parameters. For example, in a DVFSC mode focusing on low power consumption, as the operating frequency of the LPDDR chip decreases, the dynamic voltage also decreases proportionally to reduce power consumption; while in a mode focusing on high performance, the dynamic voltage needs to be maintained at a relatively high level during high-frequency operation to ensure rapid switching of transistors and high-speed data transmission.

In some optional embodiments, determining the parameter type based on the process parameters comprises: determining parameter performance based on the process parameters; when the parameter performance indicates that the process parameters are electrical performance parameters, configuring the process parameters indicating the electrical performance of transistors as a first type, and/or configuring the process parameters indicating the electrical performance of load components as a second type; when the parameter performance indicates that the process parameters are physical performance parameters, configuring the process parameters indicating the physical performance of transistors as a third type, and/or configuring the process parameters indicating the physical performance of load components as a fourth type.

Specifically, transistors are the core active components in an LPDDR chip, and their electrical performance plays a crucial role in the functional realization of the entire LPDDR chip. Process parameters such as the threshold voltage, carrier mobility, channel length, channel width, and doping concentration of transistors directly reflect their electrical characteristics. For example, the threshold voltage determines the voltage conditions under which the transistor starts to conduct, and its magnitude directly affects the static power consumption and operating speed of the chip. Carrier mobility is related to the switching speed and current driving capability of the transistor, determining electrical performance indicators such as the data read/write speed of the LPDDR chip. Therefore, these process parameters that can intuitively reflect the electrical performance of transistors are classified as the first type (corresponding symbols can be selected, such as 1α, etc., without specific limitations) to facilitate unified analysis and processing when considering factors related to the electrical performance of the chip in subsequent steps, and then determine appropriate configurations such as the DVFSC mode and dynamic voltage based on these parameters.

In addition to transistors, there are also load components such as capacitors and resistors in an LPDDR chip. Taking capacitors as an example, the size of parasitic capacitances (including the gate capacitance of transistors, parasitic capacitances between metal layers, etc.) inside the LPDDR chip affects the charge and discharge time of signals, thereby changing the signal transmission speed, and also consumes electrical energy during the charge and discharge process, affecting the power consumption of the LPDDR chip. Resistive components (such as metal wiring resistances, etc.) produce voltage drops when current passes through, affecting signal integrity and electrical energy loss. Classifying these process parameters related to the electrical performance of load components as the second type (corresponding symbols can be selected, such as 1β, etc., without specific limitations) helps to comprehensively analyze the influence of different components when considering the overall electrical performance of the LPDDR chip, and more accurately determine the operating mode and parameters such as voltage that meet the actual electrical characteristic requirements of the LPDDR chip.

Although transistors mainly function based on their electrical performance, some process parameters related to physical performance are also important. For example, the physical dimensions of transistors (including the overall size, the thickness of each layer structure, etc.) not only affect the integration density of the LPDDR chip but may also indirectly affect electrical performance. Smaller physical dimensions of transistors help to improve the integration density of the LPDDR chip to a certain extent but also bring about problems such as heat dissipation or physical stability during high-frequency operation. Additionally, physical performance parameters such as the tightness of adhesion between different material layers of transistors affect the transmission of electrons at different material interfaces, thereby indirectly affecting electrical performance. Classifying these process parameters reflecting the physical performance of transistors as the third type (corresponding symbols can be selected, such as 1X, etc., without specific limitations) allows for comprehensive consideration of the influence of physical structure factors on electrical characteristics when subsequently analyzing the overall performance of the chip and determining relevant configurations, making the determined operating mode and parameters such as voltage more in line with the actual situation of the LPDDR chip.

For load components in the LPDDR chip, physical performance parameters such as the thickness of metal layers, the spacing between metal lines, and the thickness of insulating layers directly determine the physical characteristics of the load components. The thickness of metal layers affects their conductivity and resistance characteristics, the spacing between metal lines affects the wiring capacitance and electromagnetic interference between signals, and the thickness of insulating layers is related to physical performance manifestations such as the voltage withstand capability and leakage current of the LPDDR chip. Classifying these process parameters related to the physical performance of load components as the fourth type (corresponding symbols can be selected, such as 1Y, etc., without specific limitations) enables comprehensive consideration of physical structure factors when considering the overall performance of the LPDDR chip, ensuring that the influence of physical performance parameters on the operating state of the LPDDR chip is fully taken into account when determining parameters such as the DVFSC mode and dynamic voltage of the chip, and ensuring that the LPDDR chip operates with a stable physical structure and good electrical performance.

In some optional embodiments, determining the DVFSC mode of the LPDDR chip according to the parameter type and the preset data table comprises: when the parameter type is configured as a first type, searching for a first mode corresponding to the first type in the preset data table and configuring the DVFSC mode as the first mode; when the parameter type is configured as a second type, searching for a second mode corresponding to the second type in the preset data table and configuring the DVFSC mode as the second mode; when the parameter type is configured as a third type, searching for a third mode corresponding to the third type in the preset data table and configuring the DVFSC mode as the third mode; when the parameter type is configured as a fourth type, searching for a fourth mode corresponding to the fourth type in the preset data table and configuring the DVFSC mode as the fourth mode. The first mode indicates a high-frequency mode, while the second and third modes indicate low-frequency modes.

Specifically, the first-type parameters mainly refer to process parameters that indicate the electrical performance of transistors. These parameters have a crucial impact on the electrical behavior and operational characteristics of the chip (chips referred to in this application all denote LPDDR chips). For example, situations such as high carrier mobility and short channel length of transistors (characteristics covered by first-type parameters) imply that the transistors possess strong switching speeds and current driving capabilities, enabling them to support the chip's operation at higher frequencies for rapid data read/write and processing. Therefore, from a performance perspective, chips corresponding to these parameters are more suitable for high-frequency operation modes to fully leverage their electrical performance advantages and enhance the overall operational efficiency of the chip. The preset data table is compiled after extensive chip testing, simulation analysis, and feedback from practical applications. It records the mapping relationships between different parameter types and corresponding DVFSC modes. When the parameter type is configured as the first type, the corresponding first mode is searched for in this data table. Based on past experiments and experience, the data table comprises a suitable high-frequency mode as the first mode for first-type parameters. This high-frequency mode specifies corresponding voltage and frequency adjustment strategies. For example, in this mode, a relatively high operating voltage range (such as 1.05V) is set to ensure that transistors can quickly turn on and off during high-frequency operation. Meanwhile, corresponding frequency adjustment rules are implemented to enable the chip to operate stably at high frequencies and meet the demands for high-performance data processing.

The second-type parameters refer to process parameters that indicate the electrical performance of load components. Parameters related to load components such as parasitic capacitances and resistances within the chip fall into this category. Conditions such as large parasitic capacitances (characteristics reflected by second-type parameters) will lengthen the charge and discharge times of signals, affect signal transmission speeds, and consume more electrical energy during the charge and discharge processes, which is not conducive to the chip's efficient operation at high frequencies. Meanwhile, considering factors such as power consumption and signal stability comprehensively, chips corresponding to these parameters are more suitable for operation in low-frequency modes. By reducing the operating frequency, the pressure on signal transmission and electrical energy consumption are decreased, ensuring stable data processing by the chip. Although the data transmission speed is relatively slower, a good balance can be achieved in terms of power consumption and stability. Similarly, the DVFSC mode is determined based on the preset data table. In the data table, a specific second mode corresponding to second-type parameters is set, which is defined as a low-frequency mode. In this low-frequency mode, its voltage and frequency adjustment strategies focus on reducing power consumption and maintaining signal stability. For example, a relatively low operating voltage (such as 0.9V) is set to avoid excessive electrical energy consumption on load components due to overly high voltages. At the same time, the operating frequency is adjusted to an appropriate low-frequency range, enabling the chip to operate stably in this state and meet the needs of application scenarios that do not have high real-time requirements but emphasize power consumption and stability.

The third-type parameters focus on process parameters that indicate the physical performance of transistors, such as parameters related to physical characteristics like the physical dimensions of transistors and the degree of tight adhesion between different material layers. When these physical performance parameters exhibit certain characteristics, for example, small physical dimensions of transistors may lead to heat dissipation issues or physical stability problems during high-frequency operation. Considering the impact of the physical structure on the overall performance of the chip, such chips are not suitable for long-term high-frequency operation. Otherwise, risks such as overheating and physical structure damage may occur, affecting the reliability and lifespan of the chip. Therefore, based on physical performance limitations, the chip is operated in a low-frequency mode to ensure the stability of its physical structure and the stable performance of the overall chip. According to the corresponding relationships in the preset data table, there is a corresponding third mode for third-type parameters, which is also set as a low-frequency mode. In the third mode, its DVFSC voltage and frequency adjustment rules take into account the physical performance factors of transistors. For example, based on the heat dissipation requirements and physical stability requirements of transistors, an appropriate operating voltage (such as 0.9V) is set to avoid exacerbating heat dissipation problems. At the same time, the operating frequency is controlled within a low-frequency range to ensure stable data read/write and processing by the chip under the premise of stable physical structure, extend the chip's lifespan, and ensure the stable operation of the system.

The fourth-type parameters involve process parameters that indicate the physical performance of load components, such as physical parameters like the thickness of metal layers, the spacing between metal wires, and the thickness of insulating layers. For example, unreasonable metal wire spacing may lead to increased wiring capacitance and enhanced electromagnetic interference between signals, and insufficient thickness of the insulating layer may cause problems such as electrical leakage. These physical performance issues will affect the stability and normal operation of the chip. In this case, to ensure the reliable operation of the chip and avoid problems such as signal transmission errors and electrical leakage faults caused by physical structure factors, the chip is operated in a low-frequency mode. By reducing the frequency, the pressure on the physical structure is decreased, ensuring the stability of signal transmission and the overall safety of the chip. The fourth mode corresponding to fourth-type parameters is searched for in the preset data table, which can be a low-frequency mode or a non-operating mode, etc. The DVFSC strategy in the fourth mode focuses on considering the impact of the physical performance of load components on the chip. For example, based on physical characteristics such as metal layers and insulating layers, an appropriate operating voltage is set to avoid electrical leakage risks. At the same time, the operating frequency is maintained at a low level, enabling the chip to achieve stable data processing functions while considering the physical structure stability of load components and meeting the system's requirements for chip reliability.

In some optional embodiments, determining the dynamic voltage of the LPDDR chip according to the DVFSC mode, the preset data table, and the process parameters comprises: determining a target entry in the preset data table based on the DVFSC mode; determining the dynamic voltage according to the process parameters and the target entry, wherein the dynamic voltage represents a pre-set voltage according to different process parameters.

Specifically, once the DVFSC mode adopted by the LPDDR chip is known, the corresponding section for this mode is located in the preset data table. For example, if the determined DVFSC mode of the LPDDR chip is a high-frequency mode (assuming it has been matched and determined as such based on relevant parameter types previously), then the area in the data table that specifically describes information related to the high-frequency mode is found. Within this area, an entry that matches or is closest to the actual process parameters of the current chip is further searched for, and this entry is the target entry. The corresponding dynamic voltage is extracted from the target entry, enabling the chip to operate at this dynamic voltage under the DVFSC mode, ensuring that its performance in terms of performance, power consumption, stability, and other aspects is optimized or meets established system requirements.

In some optional embodiments, after determining the target entry in the preset data table based on the DVFSC mode, the method further comprises: determining a voltage calculation formula according to the target entry; substituting the process parameters into the voltage calculation formula for calculation to obtain the dynamic voltage.

Specifically, after finding the target entry from the preset data table based on the DVFSC mode, the voltage calculation formula is extracted from this entry, and the actual process parameters of the LPDDR chip are substituted into it for calculation, thereby precisely determining the dynamic voltage of the LPDDR chip. By fully utilizing the extensive experimental and empirical data integrated in the preset data table and combining it with the specific process parameter characteristics of the chip, a precise quantitative calculation of the dynamic voltage is achieved. This ensures that the chip can operate at an appropriate voltage under a specific DVFSC mode, maintaining a good balance in terms of chip performance, power consumption, stability, and other aspects.

In some optional embodiments, determining the dynamic voltage according to the process parameters and the target entry comprises: obtaining a first voltage corresponding to the first type of process parameters in the target entry; obtaining a second voltage corresponding to the second type of process parameters in the target entry; obtaining a third voltage corresponding to the third type of process parameters in the target entry; obtaining a fourth voltage corresponding to the fourth type of process parameters in the target entry; and determining the dynamic voltage according to the first voltage, the second voltage, the third voltage, and the fourth voltage.

Specifically, by separately obtaining the voltage values associated with various types of process parameters in the target entry and then integrating these voltage values in a reasonable manner, the dynamic voltage suitable for the chip under a specific operating mode (determined by the DVFSC mode) is precisely determined. This approach can fully take into account the characteristics of the chip from multiple dimensions, ensuring that the setting of the dynamic voltage not only conforms to the physical and electrical structural characteristics of the chip but also meets its requirements for performance, power consumption, stability, and other aspects in different application scenarios.

The first type of process parameters are those closely related to the electrical performance of transistors, such as the threshold voltage, carrier mobility, channel length and width, and doping concentration of transistors. These parameters fundamentally determine the electrical behavior of transistors and, consequently, have a significant impact on the operating characteristics of the entire chip. For example, the threshold voltage determines the minimum voltage required for a transistor to start conducting. A lower threshold voltage makes the transistor more likely to conduct but may also lead to an increase in leakage current when it is in the off state, affecting the static power consumption of the chip. Carrier mobility is related to the switching speed and current driving capability of transistors. A higher carrier mobility helps achieve fast data read and write operations, improving the operating frequency and processing performance of the chip. The target entry, as a key record screened out from the preset data table for the specific situation of the current chip, sets a corresponding first voltage for the first type of process parameters. This first voltage is determined based on a large number of experimental tests, simulation analyses, and practical application experiences, taking comprehensive consideration of the electrical performance characteristics of transistors reflected by the first type of process parameters. In the target entry, a voltage value suitable for the specific DVFSC mode and the specific range or numerical value of the first type of process parameters of the current chip is clearly given as the first voltage.

In some embodiments, based on past test data of chips with similar parameters under this DVFSC mode, an appropriate first voltage value, such as 1.0V (just an example value), is given in the target entry, and this first voltage can be obtained by looking up the corresponding record.

The second type of process parameters mainly involve parameters indicating the electrical performance of load components, including characteristic parameters of load components such as parasitic capacitance and resistance within the chip. Similarly, the second voltage corresponding to the second type of process parameters is looked up in the target entry.

The third type of process parameters focus on parameters indicating the physical performance of transistors, covering the physical dimensions of transistors (such as the overall size, the thickness of each layer structure) and the degree of close fit between each material layer. Although these parameters mainly reflect the physical characteristics of transistors, they indirectly affect the electrical performance and operating state of transistors and even the entire chip. For example, smaller physical dimensions of transistors help improve the integration density of the chip but may bring about heat dissipation problems or physical stability problems during high-frequency operation. Insufficiently close fit between the material layers of transistors may affect the electron transmission efficiency at different material interfaces, thereby changing the electrical performance of transistors. Therefore, these physical performance parameters are also important factors to be considered when determining the appropriate operating voltage of the chip. The target entry records a corresponding third voltage for the third type of process parameters. When the physical performance parameters of transistors in the chip present a specific situation (such as small physical dimensions and average fit between material layers), taking into account a comprehensive consideration of the stability and electrical performance of the chip under the current DVFSC mode, a corresponding third voltage value is specified in the target entry. For example, according to the record in the target entry, for chips with such transistor physical performance characteristics, the third voltage is set to 0.9V (just for illustration) under this DVFSC mode. By obtaining the voltage correspondence information related to the physical performance parameters of transistors in the target entry, this third voltage can be obtained, which reflects the voltage suitable for ensuring the stable operation of the chip from the perspective of the physical structure of transistors.

The fourth type of process parameters focus on parameters indicating the physical performance of load components, such as the thickness of metal layers, the spacing between metal wires, and the thickness of insulating layers. These physical parameters directly determine the physical characteristics of load components and have an impact on the stability, signal transmission, and power consumption of the chip. The fourth voltage corresponding to the fourth type of process parameters is looked up in the target entry.

In some embodiments, based on the actual situation of the physical performance parameters of the chip's load components, and taking into comprehensive consideration the requirements for maintaining chip stability, ensuring signal transmission quality, and controlling power consumption under the current DVFSC mode, a corresponding fourth voltage value is given. For example, if the metal layer of the chip is relatively thin, the spacing between metal wires is moderate, and the thickness of the insulating layer is within a certain range (these are the actual states of the fourth-type process parameters), according to relevant experience and test data, a fourth voltage of 0.7V (an example value) will be set accordingly. By locating the part related to the physical performance of load components in the target entry, this fourth voltage can be obtained, which reflects the voltage that should be set from the perspective of the physical structure of load components to enable the chip to operate normally.

In some optional embodiments, determining the dynamic voltage according to the first voltage, the second voltage, the third voltage, and the fourth voltage comprises: obtaining a first weight coefficient for the first voltage, a second weight coefficient for the second voltage, a third weight coefficient for the third voltage, and a fourth weight coefficient for the fourth voltage; and calculating the dynamic voltage according to the first voltage, the first weight coefficient, the second voltage, the second weight coefficient, the third voltage, the third weight coefficient, the fourth voltage, and the fourth weight coefficient.

Specifically, by assigning corresponding weight coefficients (the first weight coefficient, the second weight coefficient, the third weight coefficient, and the fourth weight coefficient) to the voltages corresponding to different types of process parameters (the first voltage, the second voltage, the third voltage, and the fourth voltage) respectively, and then performing weighted calculations based on these weight coefficients, a dynamic voltage value that comprehensively considers various characteristics of the chip is obtained. This more precisely fits the complex situation of the chip in actual operation, fully takes into account the differences in the impact of different process parameters on the chip's voltage requirements, and ensures that the determined dynamic voltage can enable the chip to achieve a good balance in terms of performance, power consumption, and stability, and ensure the stable and efficient operation of the chip under the corresponding DVFSC mode.

The first weight coefficient (corresponding to the first voltage, which is the voltage corresponding to process parameters related to the electrical performance of transistors): it reflects the relative importance of the electrical performance parameters of transistors in the overall voltage requirements of the chip. For example, electrical performance parameters of transistors such as threshold voltage and carrier mobility have a crucial impact on whether the chip can start normally, work efficiently at what frequency, and its power consumption level. If the working performance and power consumption of the chip are highly sensitive to the electrical performance of transistors, for example, in some application scenarios with extremely high requirements for data processing speed, the switching speed of transistors (closely related to carrier mobility) plays a decisive role. Then the first weight coefficient will be relatively large to highlight the importance of the first voltage corresponding to these parameters in determining the dynamic voltage.

The second weight coefficient (corresponding to the second voltage, which is the voltage corresponding to process parameters related to the electrical performance of load components): it reflects the proportion of the electrical performance parameters of load components in the overall voltage requirements of the chip. The electrical performance of load components such as parasitic capacitance and resistance within the chip has a significant impact on signal transmission speed and power loss. In some applications with high requirements for signal integrity or strict power consumption limits, the impact of the electrical performance parameters of load components cannot be ignored. At this time, the second weight coefficient will be reasonably set according to its importance to reflect the role of the second voltage in comprehensively determining the dynamic voltage.

The third weight coefficient (corresponding to the third voltage, which is the voltage corresponding to process parameters related to the physical performance of transistors): it mainly considers the weight of the impact of the physical performance parameters of transistors on the chip's voltage requirements. Although the physical performance parameters of transistors (such as physical dimensions and the degree of close fit between material layers) indirectly affect the electrical performance of the chip, excessively small physical dimensions of transistors may lead to heat dissipation problems, which in turn affect the stable operation of the chip under high loads and require appropriate voltage adjustments to alleviate. Therefore, the third weight coefficient is determined according to the degree of impact of these physical performance parameters on the overall performance and stability of the chip, indicating the proportion of the third voltage in the final determination of the dynamic voltage.

The fourth weight coefficient (corresponding to the fourth voltage, which is the voltage corresponding to process parameters related to the physical performance of load components): it represents the importance of the physical performance parameters of load components in the chip's voltage setting. For example, physical performance parameters of load components such as the thickness of metal layers, the spacing between metal wires, and the thickness of insulating layers are related to the stability, signal electromagnetic interference, and leakage situation of the chip. In terms of ensuring the reliable operation of the chip and avoiding failures caused by physical structure factors, these parameters play a key role. Correspondingly, the fourth weight coefficient will be assigned an appropriate value according to its importance.

The corresponding weight coefficients are determined based on the performance objectives that the chip prioritizes in different application scenarios, such as high performance computing (where the weight coefficient related to the electrical performance of transistors is larger) and low-power-consumption and long-battery-life scenarios (where the weight coefficients related to the electrical and physical performance of load components are larger). For example, for LPDDR chips used in mobile devices, which are relatively sensitive to power consumption, the second weight coefficient (related to the impact of the electrical performance of load components on power consumption) and the fourth weight coefficient (related to the physical performance of load components ensuring stability and low leakage to save power) may be relatively increased to ensure that the requirement for reducing power consumption is fully considered when determining the dynamic voltage. Assume that the first voltage V₁=1.2V, the first weight coefficient ω₁=0.3; the second voltage V₂=1.0V, the second weight coefficient ω₂=0.25; the third voltage V₃=0.9V, the third weight coefficient ω₃=0.2; the fourth voltage V₄=0.8V, the fourth weight coefficient ω₄=0.25. The calculation yields: the dynamic voltage V_{D}=1.2×0.3+0.25×1.0+0.2×0.9+0.25×0.8=0.99V. Determining the dynamic voltage through such a weighted calculation method can comprehensively consider various characteristics of the chip, ranging from the electrical performance of transistors, the electrical performance of load components, the physical performance of transistors to the physical performance of load components.

The setting of different weight coefficients ensures that the proportion of the voltages corresponding to process parameters in different parts in the final dynamic voltage aligns with their actual impacts on the overall chip. This avoids the problem of a single factor dominating or certain factors being overlooked, making the determined dynamic voltage more scientific and reasonable. It can better meet the precise voltage requirements of the chip under different working states and application scenarios, ensuring the stable and efficient operation of the chip under the established DVFSC mode and achieving optimization and coordination in terms of performance, power consumption, and stability.

Implementing the embodiments of the present disclosure offers the following beneficial effects. The embodiments of the present disclosure provide a method for determining the dynamic voltage of an LPDDR chip, which comprises the following steps: obtaining process parameters of the LPDDR chip; determining parameter types based on the process parameters, wherein the parameter types characterize the types of the process parameters; determining the DVFSC mode of the LPDDR chip based on the parameter types and a preset data table; and determining the dynamic voltage of the LPDDR chip based on the DVFSC mode, the preset data table, and the process parameters. This application can effectively compensate for the deficiencies of existing methods. By using the process parameters of the LPDDR chip, it determines the DVFSC mode of the LPDDR chip and then calculates the dynamic voltage under that DVFSC mode. Therefore, when the DVFSC mode is a low-frequency mode, it can calculate the corresponding dynamic voltage, enhancing the stability of the LPDDR chip's operation.

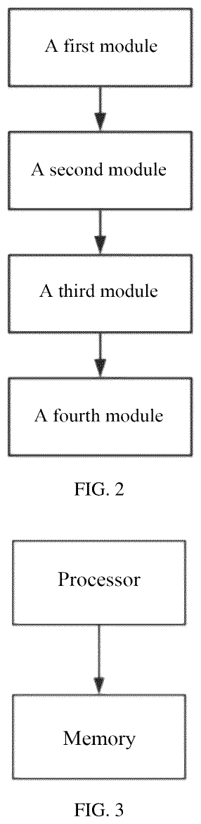

Secondly, with reference to FIG. 2, the embodiments of the present disclosure provide a system for determining the dynamic voltage of an LPDDR chip, which comprises:
a first module configured to obtain process parameters of the LPDDR chip;
a second module configured to determine parameter types based on the process parameters, wherein the parameter types characterize the types of the process parameters;
a third module configured to determining the DVFSC mode of the LPDDR chip based on the parameter types and a preset data table;
a fourth module configured to determine the dynamic voltage of the LPDDR chip based on the DVFSC mode, the preset data table, and the process parameters.

It can be seen that the content in the above method embodiments is applicable to this system embodiment. The specific functions achieved by this system embodiment are the same as those in the above method embodiments, and the beneficial effects achieved are also the same.

Thirdly, with reference to FIG. 3, the embodiments of the present disclosure provide a memory testing device, which comprises:
at least one processor;
at least one memory for storing at least one program;
when the at least one program is executed by the at least one processor, it enables the at least one processor to implement the above method.

It can be seen that the content in the above method embodiments is applicable to this device embodiment. The specific functions achieved by this device embodiment are the same as those in the above method embodiments, and the beneficial effects achieved are also the same.

Fourthly, in addition, the embodiments of this application also disclose a computer program product or computer program stored on a computer-readable storage medium. The processor of a computer device can read this computer program from the computer-readable storage medium, and the processor executes the computer program, enabling the computer device to perform the above method or the above system. Similarly, the content in the above method embodiments is applicable to this storage medium embodiment. The specific functions achieved by this storage medium embodiment are the same as those in the above method embodiments, and the beneficial effects achieved are also the same.

It is understandable that all or some of the steps and systems in the methods disclosed above can be implemented as software, firmware, hardware, or an appropriate combination thereof. Some or all physical components can be implemented as software executed by a processor, such as a central processing unit, a digital information processor, or a microprocessor, or as hardware, or as integrated circuits, such as application-specific integrated circuits. Such software can be distributed on computer-readable media, which can comprise computer storage media (or non-transitory media) and communication media (or transitory media). As commonly known to those skilled in the art, the term computer storage media comprises volatile and non-volatile, removable and non-removable media implemented in any method or technology for storing information, such as computer-readable instructions, data structures, program modules, or other data. Computer storage media comprise, but are not limited to, RAM, ROM, EEPROM, flash memory, or other memory technologies, CD-ROMs, digital versatile discs (DVDs), or other optical disc storage, magnetic cassettes, magnetic tapes, magnetic disk storage, or other magnetic storage devices, or any other medium that can be used to store desired information and can be accessed by a computer. Additionally, as commonly known to those skilled in the art, communication media typically contain computer-readable instructions, data structures, program modules, or other data in modulated data signals, such as carrier waves or other transmission mechanisms, and can comprise any information delivery medium.

The above description, in conjunction with the accompanying drawings, provides a detailed explanation of the embodiments of the present disclosure. However, the present disclosure is not limited to the above embodiments, and various changes can be made within the scope of knowledge possessed by those skilled in the art without departing from the spirit of the present disclosure.

1. A dynamic voltage determination method for an LPDDR chip, comprising:
obtaining process parameters of the LPDDR chip;
determining a parameter type based on the process parameters, wherein the parameter type represents a type of the process parameters;
determining a DVFSC mode of the LPDDR chip based on the parameter type and a preset data table;
determining a dynamic voltage of the LPDDR chip based on the DVFSC mode, the preset data table, and the process parameters, comprising: identifying a target entry in the preset data table based on the DVFSC mode, obtaining a first voltage corresponding to the process parameters of a first type in the target entry, obtaining a second voltage corresponding to the process parameters of a second type in the target entry, obtaining a third voltage corresponding to the process parameters of a third type in the target entry, obtaining a fourth voltage corresponding to the process parameters of a fourth type in the target entry, and determining the dynamic voltage based on the first voltage, the second voltage, the third voltage, and the fourth voltage, wherein the dynamic voltage represents a preset voltage according to different process parameters.

2. The method according to claim 1, wherein determining the parameter type based on the process parameters comprises:
determining parameter performance based on the process parameters;
configuring the process parameters indicating transistor electrical performance as the first type, and/or configuring the process parameters indicating load element electrical performance as the second type, when the parameter performance indicates that the process parameters are electrical performance parameters;
configuring the process parameters indicating transistor physical performance as the third type, and/or configuring the process parameters indicating load element physical performance as the fourth type, when the parameter performance indicates that the process parameters are physical performance parameters.

3. The method according to claim 2, wherein determining the DVFSC mode of the LPDDR chip based on the parameter type and the preset data table comprises:
searching for a first mode corresponding to the first type in the preset data table and configuring the DVFSC mode as the first mode, when the parameter type is configured as the first type;
searching for a second mode corresponding to the second type in the preset data table and configuring the DVFSC mode as the second mode, when the parameter type is configured as the second type;
searching for a third mode corresponding to the third type in the preset data table and configuring the DVFSC mode as the third mode, when the parameter type is configured as the third type;
searching for a fourth mode corresponding to the fourth type in the preset data table and configuring the DVFSC mode as the fourth mode, when the parameter type is configured as the fourth type, wherein the first mode indicates a high-frequency mode;
and the second mode and the third mode indicate low-frequency modes.

4. The method according to claim 1, wherein the determining the dynamic voltage according to the first voltage, the second voltage, the third voltage, and the fourth voltage comprises:
obtaining a first weight coefficient for the first voltage, a second weight coefficient for the second voltage, a third weight coefficient for the third voltage, and a fourth weight coefficient for the fourth voltage;
calculating the dynamic voltage according to the first voltage, the first weight coefficient, the second voltage, the second weight coefficient, the third voltage, the third weight coefficient, the fourth voltage, and the fourth weight coefficient.

5. A dynamic voltage determination system for an LPDDR chip, comprising:
a first module configured to obtain process parameters of the LPDDR chip;
a second module configured to determine a parameter type based on the process parameters, wherein the parameter type represents the type of the process parameters;
a third module configured to determine a DVFSC mode of the LPDDR chip based on the parameter type and a preset data table;
a fourth module configured to determine a dynamic voltage of the LPDDR chip based on the DVFSC mode, the preset data table, and the process parameters, comprising: identifying a target entry in the preset data table based on the DVFSC mode, obtaining a first voltage corresponding to the process parameters of a first type in the target entry, obtaining a second voltage corresponding to the process parameters of a second type in the target entry, obtaining a third voltage corresponding to the process parameters of a third type in the target entry, obtaining a fourth voltage corresponding to the process parameters of a fourth type in the target entry, and determining the dynamic voltage based on the first voltage, the second voltage, the third voltage, and the fourth voltage, wherein the dynamic voltage represents a preset voltage according to different process parameters.

6. A memory testing device, comprising:
at least one processor;
at least one memory for storing at least one program;
when the at least one program is executed by the at least one processor, enabling the at least one processor to implement the method as claimed in claim 1.
